(19) United States
(12) Patent Application Publication
(10) Pub. No.: US 2005/0110050 A1
(43) Pub. Date: May 26, 2005

(54) Planarization of an image detector device for improved spectral response

(76) Inventors: Tom Walschap, Sint-Amands (BE); Herman Witters, Evergem (BE); Danny Scheffer, Clinge (NL); Jan Bogaerts, St-Katelijne-Waver (BE); Bart Dierickx, Edegem (BE)

Correspondence Address: BARNES & THORNBURG, P.O. BOX 2786, CHICAGO, IL, 60690-2786, US

(21) Appl. No.: 10/717,854

(22) Filed: Nov. 20, 2003

(51) Int. Cl. H01L 27/148; H01L 21/00

(52) U.S. Cl. 257/222; 257/437; 438/72

(57) ABSTRACT

An image sensor device (100) is described comprising a semiconductor substrate (1), a MOS-based pixel structure and a planarization layer (30) on top. The planarization layer (30) is provided to avoid lensing due to the roughness of the pixel structure surface. The planarization layer (30) may be further optimized by adapting its thickness and refractive index to obtain anti-reflective coating properties for some regions in the image sensor device. This allows increasing the quantum efficiency and the spectral response of the image sensor device significantly.

### TECHNICAL FIELD OF THE INVENTION

The present invention relates to an image sensor device that has an improved spectral response. In particular the invention relates to an image sensor device having a planarization layer on top of the device structure to improve the quantum efficiency of the device.

### BACKGROUND OF THE INVENTION

Nowadays, image sensor devices, both charge-coupled devices (CCD's) and CMOS image sensor devices, are widely used: e.g. in astronomical telescopes, scanners, video camcorders, cell phones, bar code readers, etc.

When color filters need to be used in the image sensor devices, it is a known technique to provide a planarization layer on top of the sensor to obtain a flat surface. The planarization layer is applied to the layer or stack of layers of the image sensor to obtain a leveled surface topology for subsequent deposition of color filters on the flattened surface. The availability of a flat surface is important as color filters are often based on diffraction and interference effects in stacks of thin films forming the color filter, each thin film having its specific index of refraction and the optical path length of incident light in the different thin films playing an important role in the color filtering properties. This optical path length, and therefore the color filtering properties of the corresponding filter, can only be guaranteed for stacks made on a flat surface. Planarization techniques are well known in several thin or thick film applications and semiconductor applications.

In CMOS image sensor devices, planarization is only done to planarize the wafer after CMOS processing for subsequent deposition of color filters. Therefore, in monochrome image sensor devices, i.e. sensors without additional color filters applied, the step of planarization after CMOS processing is not performed, as this takes an additional step in the production method of the image sensor and thus complicates the production process. Furthermore, up to now there was no reason to perform this additional step of planarization after CMOS processing.

The quality of monochrome image sensor devices is mainly determined by their spectral response and quantum efficiencies. The quantum efficiency of monochrome image sensor devices is, besides other things, determined by reflection, transmission and absorption of the light incident on the detector. In particular the amount of reflected light plays an important role: the light reflected at the surface of the image sensor cannot contribute anymore to the signal to be detected by the sensor, as it does not generate charge carriers for detection, thus leading to a reduced quantum efficiency of the sensor. A well known technique of avoiding loss of light intensity due to reflection and therefore of improving the quantum efficiency is applying an anti-reflective coating (ARC).

Anti-reflective coatings (ARC) are known to be used in several applications where it is important to reduce reflection, e.g. minimize glare in displays, mobile phones, navigation systems, glasses etc. or where it is important to have an optimum transmission and/or absorption, like in detectors. These ARCs can reduce the amount of reflected light to nearly zero. Hence quantum efficiencies of the sensor could be increased to near 100%. In order to have a true anti-reflective coating, the thickness of such a layer should be homogeneous over the whole underlying substrate, thus it follows the topology of the layers underneath it. The optical thickness of a single-layer anti-reflective coating should be an odd number of quarter wavelengths of the light the anti-reflective coating is designed for,

$${n}_{ARC} . {d}_{ARC} = ( 2 l + 1 ) \cdot \frac{λ}{4} \qquad ( 1 )$$

wherein n_{ARC} is the refractive index of the antireflective coating, d_{ARC} is the physical thickness of the antireflective coating, I is a positive integer and λ is the wavelength of the light for which the ARC is developed. In this way, the optical path difference equals a number of half wavelengths of the light the anti-reflective coating is designed for, so that destructive interference occurs between the light reflected at the top of the anti-reflective coating and the light reflected at the ARC/device interface.

The refractive index of a single layer ARC should preferably be chosen so that the intensity of both reflected beams, i.e. of the light beam reflected at the top of the anti-reflective coating and of the light beam reflected at the interface ARC/device, is identical. This can be obtained if the refractive index of the coating fulfils the following equation

$$\begin{matrix}\frac{{n}_{air}}{{n}_{ARC}} = \frac{{n}_{ARC}}{{n}_{device}} or \\ {n}_{ARC} = \sqrt{{n}_{device}}\end{matrix} \qquad ( 2 )$$

wherein n_{device} is the refractive index of the layer on which the ARC is deposited. For optimum anti-reflection coatings both conditions, expressed by equation (1) and equation (2) should be fulfilled. In practice, at least the thickness condition is fulfilled as it can be difficult to find thin film materials having the exact refractive index to fulfill the refractive index condition.

Besides single-layer anti-reflective coatings, stacks of layers are also often used for ARC. The type of materials used for anti-reflective coatings strongly depends on the wavelength or wavelength range for which the ARC must be optimized and the refractive index of the carrier material, i.e. the layer on which the ARC is deposited. MgF₂ coatings are often used as anti-reflective coating on glass, whereas most common ARC stacks are stacks of alternating dielectric layers of silicon dioxide and titanium dioxide. It is also possible to use organic materials as anti-reflective coatings. A further description of anti-reflective coatings can be found in e.g. Selected Papers on Characterization of Optical Coatings, M. R. Jacobson & B. J. Thompson, p 515-521 and its references.

A known problem for devices having a rough or curved surface, such as e.g. image sensor devices, is that a lensing effect occurs. This effect, based on refraction, leads to focussing of incident light to a point or an area in the device if the surface shows a hill, whereas it leads to defocusing of incident light in the device if the surface shows a valley. Depending on the device this can introduce additional problems. Due to their homogeneous thickness which inherently leads to a curved surface when applied onto a curved surface, anti-reflective coatings cannot properly solve the lensing problem.

### SUMMARY OF THE INVENTION

It is an object of the present invention to reduce or overcome the above mentioned lensing problem in image sensor devices. It is a further object of the present invention to improve the spectral response and quantum efficiency of a detector device preferably without relying on expensive and difficult manufacturing processes.

The above objectives are accomplished by a monochrome image sensor device according to the present invention. The monochrome image sensor device comprises a substrate and a pixel structure. The monochrome image sensor device furthermore comprises a planarisation layer on top of the pixel structure, whereby the planarisation layer at the same time is an anti reflective coating. This has as advantage that lensing effects by a non-flat surface of the pixel structure are substantially reduced or even avoided. The thickness of said planarisation layer and the refractive index of the layer can be optimized to also act as an anti-reflection medium for at least one region of the image sensor device. In this way, the anti-reflection properties are further improved. However, also if the thickness of the planarisation layer is not optimized, it acts as an anti reflective coating. The planarisation layer can be a polymer, preferably a photoresist. The pixel structure in the monochrome image sensor device preferably is a MOS-based pixel structure. It can be either an active pixel or a passive pixel structure.

The planarisation layer may comprise a stack of films. In this case more reflections occur. Preferably, the index of refraction of the films in the stack changes gradually from the refractive index of the material surrounding the monochrome sensor device, or a value that is as close as possible to this refractive index of the material surrounding the monochrome sensor device, to the value of the refractive index of a top layer of said pixel structure.

In a preferred embodiment the planarisation layer of the monochrome image sensor device has a stack of layers with a monotone continuously varying refractive index.

In another embodiment an additional anti-reflective coating is deposited on top of the planarisation layer.

The present invention also provides a method for making a monochrome image sensor device comprising the steps of providing a substrate, applying a pixel structure on or in the substrate and providing a planarisation layer on top of the pixel structure. This planarisation layer on top of the pixel structure avoids lensing effects by a non-flat surface of the pixel structure. Applying the pixel structure may comprise the use of MOS-based processing technology. The planarisation layer can be formed using any method which allows to create a flat surface. The planarisation layer may be made using spin coating or dip coating. The planarisation layer may be made by providing a stack of films. This stack of films may have gradually changing refractive indexes. The method of making the monochrome image sensor may further comprise depositing a real anti-reflective coating on top of the planarisation layer.

The invention furthermore also provides a method for improving light impingement on a monochrome image sensor device. The method comprises providing a planarisation layer on top of a pixel structure of said image sensor device whereby the planarisation layer is at the same time an anti-reflective coating to avoid a lensing effect.

These and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1 shows a possible pixel structure for a monochrome image sensor device according to prior art.

FIG. 2 shows a schematic representation of a monochrome image sensor device structure according to a first embodiment of the present invention.

FIG. 3 illustrates optical refraction of light incident substantially perpendicular to the plane of the substrate of a monochrome image sensor device according to the prior art.

FIG. 4 illustrates optical refraction of light incident substantially perpendicular to the plane of the substrate of a monochrome image sensor including a planarization layer on top of the pixel structure, according to an embodiment of the present invention.

FIG. 5 compares the spectral response and quantum efficiency of a monochrome image sensor with and without planarization layer on top of the pixel structure.

FIG. 6 shows a schematic representation of a monochrome image sensor device structure according to another embodiment of the present invention.

FIG. 7 shows a schematic representation of a monochrome image sensor device structure according to a further embodiment of the present invention.

In the drawings, the same reference figures refer to the same or analogous elements.

### DESCRIPTION OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. Where the term “comprising” is used in the present description and claims, it does not exclude other elements or steps.

The present invention relates to a monochrome image sensor. The term “monochrome” in “monochrome image sensor” is used to determine that the image sensor comprises no color filters (black/white image sensor), or in other words that during fabrication of the image sensor, no color filters are deposited on top of the MOS-based pixel. Therefore, according to the prior art, previously no additional planarization layer was applied on top of the pixel in these monochrome image sensor devices as there was no need for depositing color filters and as planarization is only done to have a leveled surface to subsequently deposit e.g. color filters. Avoiding the planarization layer reduces the complexity of the device processing so the production of the device is stopped after the passivation step.

In a first embodiment of the present invention, a monochrome image sensor is provided comprising a substrate, a MOS-based pixel and a planarization layer on top. In embodiments of the present invention, the term “substrate” may include any underlying material or materials that may be used, or upon which a device, a circuit or an epitaxial layer may be formed. In other alternative embodiments, this “substrate” may include a semiconductor substrate such as e.g. a doped silicon, a gallium arsenide (GaAs), a gallium arsenide phosphide (GaAsP), an indium phosphide (InP), a germanium (Ge), or a silicon germanium (SiGe) substrate. The “substrate” may include for example, an insulating layer such as a SiO₂ or an Si₃N₄ layer in addition to a semiconductor substrate portion. Thus, the term substrate also includes silicon-on-glass, silicon-on sapphire substrates. The term “substrate” is thus used to define generally the elements for layers that underlie a layer or portions of interest. Also, the “substrate” may be any other base on which a layer is formed, for example a glass or metal layer. In the following reference will be made to silicon processing as silicon semiconductors are commonly used, but the skilled person will appreciate that the present invention may be implemented based on other semiconductor material systems and that the skilled person can select suitable materials as equivalents of the dielectric and conductive materials described below. Subsequently, a pixel structure, e.g. a MOS-based pixel structure, is formed in or on the substrate. The pixel structure may form an active or a passive pixel. Furthermore, the pixel structure may be any pixel structure available.

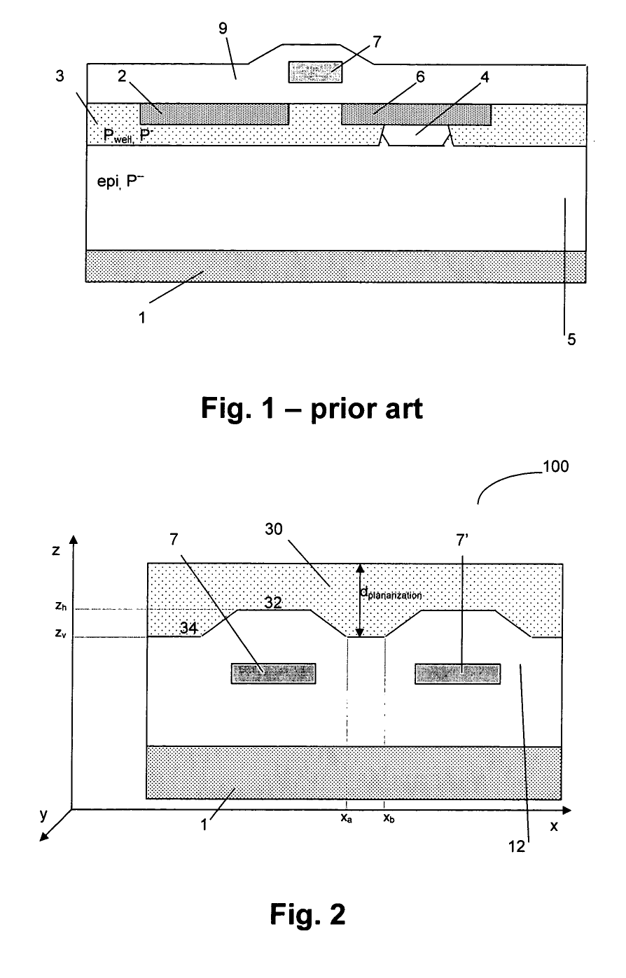

A prior art pixel is illustrated in FIG. 1. This pixel has a barrier layer 3 between a radiation sensitive volume 5 in a semiconductor substrate 1 and regions 2 connected to readout circuitry (not represented in the drawings), and no or a lower barrier 4 between the radiation sensitive volume 5 in the semiconductor substrate 1 and the regions 6 adapted and meant for collecting the charge carriers being generated by the radiation in the radiation sensitive volume. The pixel furthermore has a gate 7. The region forming the barrier layer 3 in between the radiation sensitive volume 5 wherein charges are created and the unrelated electronics 2 of the readout circuitry can have dopants of the same conductivity type as the radiation sensitive volume 5, for example a p-well in a p type substrate. The region 4 generating no barrier may be a region of inverse conductivity type as the conductivity type of the substrate, for example a n-well in a p type substrate. Such a pixel has a higher fill factor than a pixel having no barrier region 3. To improve the gain of the image sensor, the number of circuits comprising a gate, a doped region and a detection circuitry can be increased. On top of the pixel structure, a passivation layer 9 is provided.

The example of the pixel structure shown in FIG. 1 is given for illustrative reasons only. The above described pixel structure is preferably fabricated by MOS processing technology. It will be appreciated by a person skilled in the art that any other pixel structure available can be used.

According to a fist embodiment of the present invention, an image sensor device is finished by adding a planarization layer on top of the pixel structure. In case a stack of different pixel structures, often separated by planarization layers, is present, it is an important feature of the present invention to add a planarization layer to the top of the final pixel structure. A schematic view of a monochrome image sensor device according to this first embodiment of the present invention, is illustrated in FIG. 2, the image sensor device having two collecting circuits to increase the gain. It shows the semiconductor substrate 1, part of the pixel structure formed in the semiconductor substrate, i.e. gates 7 and 7′ and covering dielectric layer 12, and a planarization layer 30.

As mentioned, the pixel structure is preferably made using MOS-technology. The metal gates typically consist of metals, inherently having a relatively high reflection coefficient. The covering dielectric layer, e.g. oxide layer 12, i.e. the final layer of the MOS stack forming the pixel structure, may comprise, for example, glass—SiO₂ or SiN or a mixtures of these. The thickness of these covering dielectric layers typically is between 3 μm and 10 μm, preferably as thin as possible for optical reasons. The surface of the dielectric layer 12 follows the topology of the underlying structure, which is mainly determined by the metal gates 7, 7′. In FIG. 2, a co-ordinate system with axes x, y, z is introduced for the ease of explanation. The substrate 1 lies in an x, y-plane, and the z-direction is perpendicular to the plane of the substrate 1. The distance d between the maximum z value zₕ at the hills 32 of the planarisation layer 30/dielectric 12 interface and the minimum value zᵥ at the valleys of the planarisation layer 30/dielectric 12 interface, is between 0 nm (not included) and 0.5 μm, typically about 0.1 μm. Other parameters like standard roughness parameters could also be used to express this surface roughness.

The planarization layer 30 may be a polymer. This can be a photoresist, e.g. polyimide, spin-on glass, benzocyclobutene (BCB) or a type of cross-linked polymers, although other materials can be used. Preferably, these materials are applied to the device surface using spin coating or dip coating, although other suitable methods, allowing to produce a flat layer, can be used. These cheaper production processes are preferred above expensive production steps like chemical or physical vapor deposition processes. Instead of depositing an additional planarisation layer, it is also possible to use chemical mechanical planarisation techniques to obtain a flat surface.

The refractive index n_{planarization} of the planarization layer 30 is preferably between the refractive index of surrounding material, and the refractive index n_{dielectric} of the covering dielectric layer 12 at the top of the pixel structure. For example the refractive index n_{planarization} of the planarization layer 30 may be e.g. between 1, i.e. the refractive index of the environment, e.g. air, and the refractive index n_{dieiectric} of the covering dielectric layer 12 at the top of the pixel structure.

The thickness of the planarization layer 30 is inhomogeneous, so as to level the roughness of the pixel structure of the device. The maximum thickness of the planarization layer d_{planarization} depends on the roughness of the pixel structure in the image sensor to be leveled. It is preferably between 0.01 μm and 1 μm, more preferably between 0.01 μm and 0.5 μm. The roughness of the surface of the image sensor device can thereby be significantly reduced compared to the roughness prior to planarisation, e.g. it can be reduced to 50% or less of the roughness, more preferably to 10% or less of the roughness.

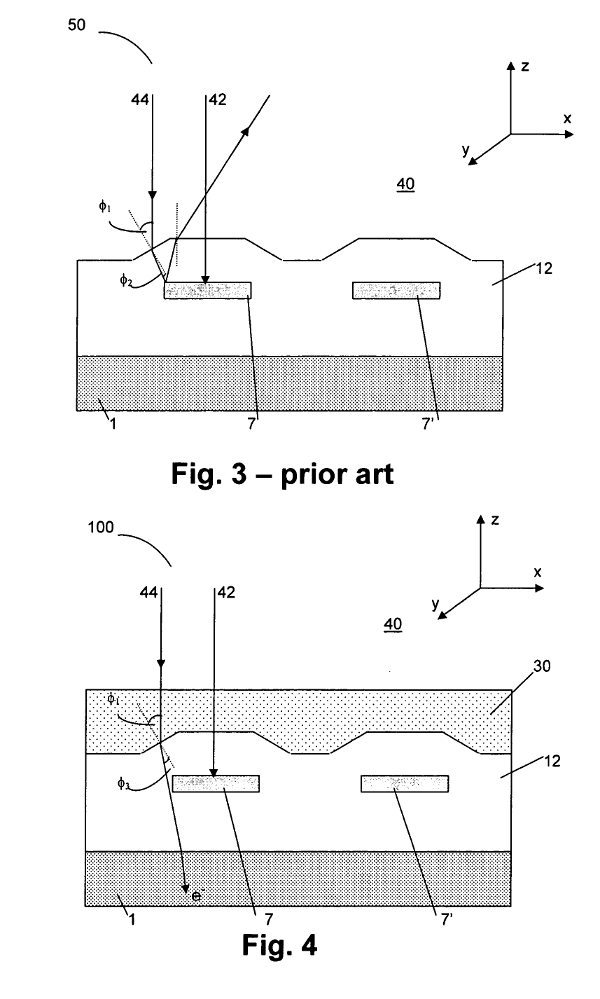

One of the main advantages of applying a final planarization layer is that it reduces the lensing effect created by the surface roughness of the device. This is illustrated in FIGS. 3 and 4, showing the optical path of light rays that are incident along the z direction of the device, substantially perpendicular to the plane of the substrate 1, for respectively a monochrome image sensor device without a planarization layer, i.e. as known from prior art, and a monochrome image sensor device with a planarization layer 30 according to the present invention. The detector is surrounded with a surrounding material 40. If this surrounding material is air, the refractive index of the surrounding material is 1, whereas the dielectric layer 12 has a refractive index n_{dielectric} which in the case of SiO₂ is about 1.6. The planarization layer has a refractive index n_{planarization} and the substrate has a refractive index n_{substrate}. Refraction of the light rays between a first and a second medium is determined by the refraction law of Snellius, i.e.
n₁. sin θ₁=n₂. sin θ₂ (3)
wherein n₁ and θ₁ are resp. the refractive index of the first medium and the angle of propagation of the light in the first medium, i.e. the angle between the perpendicular direction to the interface between the first and the second medium and the direction of incidence of light on that interface; and n₂ and θ₂ are resp. the refractive index of the second medium and the angle of refraction, i.e. the angle between the perpendicular direction to the interface and the direction of propagation of the light in the second medium.

FIG. 3 shows the lensing effect for incident light refracted at the surface of an image sensor detector device 50 without a planarization layer. Light rays 42, 44 incident perpendicular to the interface surrounding material 40/dielectric layer 12, i.e. the surface of the device, are not refracted and enter the top dielectric layer in the direction of incidence, i.e. the z direction with the coordinate system given. This is illustrated by light ray 42. Depending on the place where light ray 42 enters the image sensor device, light ray 42 can be transmitted to the semiconductor substrate or possibly be reflected by the metal gates 7, 7′. If the surface is curved, there are also light rays which are incident to the dielectric layer 12 making an angle π/2−φ₁ with the surface, φ₁ being the angle between the direction of incidence of the light and the direction perpendicular to the device's surface. This is illustrated by light ray 44. Light ray 44 is then refracted in the dielectric layer 12 making an angle φ₂ with the perpendicular to the device's surface. According to equation 3, the angle φ₂ is smaller than the angle φ₁ as light ray 44 goes from a medium with lower refractive index to a medium with higher refractive index. The actual value of the angle φ₂ is determined by the angle of incidence and the refractive index of the dielectric. The curved surface of the image sensor detector device acts thus as a lensing medium, deflecting the light rays 44 to the direction of the metal gates 7 and 7′. Due to the high reflective coefficients of metals, the metal gates 7, 7′ reflect a large amount of incident light, leading to e.g. the reflection of light rays 44 back to the interface surrounding material 40/dielectric layer 12. The light ray 44 is then subsequently reflected outside the image sensor device. Consequently, light ray 44 does not reach the semiconductor surface, therefore can not create photocharge and consequently does not contribute to the detection signal produced by the image sensor device.

When a planarization layer 30 is used on top of the dielectric layer 12, according to the teaching of the present invention, this problem can be partially solved. FIG. 4 represents a similar image sensor device 100 as FIG. 3, with an additional planarization layer 30 on top of the dielectric layer 12. As described above, the planarization layer preferably consists of a material having a refractive index in between the refractive index of surrounding material, e.g. 1.0 for air, and the refractive index n_{dielectric} of the dielectric layer 12. In this case, all incident light rays incident from the z direction enter the top layer, i.e. the planarisation layer 30, as the direction of incidence is perpendicular to the surface, i.e. the interface surrounding material 40/planarization layer 30. Therefore, all light rays propagate in the same direction of incidence, i.e. the z-direction, in the planarization top layer 30. When light ray 42 reaches the interface between planarization layer 30 and the dielectric layer 12, it again propagates in the same direction, as the direction of incidence of light ray 42 is perpendicular to the surface of the interface planarization layer 30/dielectric layer 12. Again, light ray 42 is subsequently either reflected on a metal gate 7, 7′ or reaches the semiconductor substrate 1. Light ray 44 reaches the planarization layer 30/dielectric 12 interface under an angle φ₁, i.e. the same angle as in the case of no planarization layer. Although it is also refracted, thereby making an angle φ₃ with the perpendicular direction on the surface of the dielectric, the difference between the angle of incidence φ₁ and the angle of refraction φ₃ is smaller than the difference between the angle of incidence and the angle of refraction in the case of absence of the planarization layer 30. This is due to the refractive index of the planarization layer 30 being closer to the refractive index of the dielectric layer 12, than the refractive index of air (or other surrounding material) does. Therefore, the lensing effect in the image sensor device according to the present invention is reduced. Consequently, the amount of light refracted to the metal gates 7, 7′ and subsequently reflected by the metal gates 7, 7′ will be limited, thus increasing the amount of light that reaches the semiconductor substrate 1 and therefore increasing the photocharge and the spectral response of the image sensor device 100.

From the above description and from equation (3), it can be seen that the refractive index of the planarization layer 30 preferably is close to the refractive index of the dielectric layer 12: the smaller the difference between the refractive index of the planarization layer 30 and the refractive index of the dielectric layer 12, the smaller the difference between the angle of incidence and the angle of refraction will be for the transition from planarisation layer 30 and dielectric layer 12, and therefore the smaller the lensing effect.

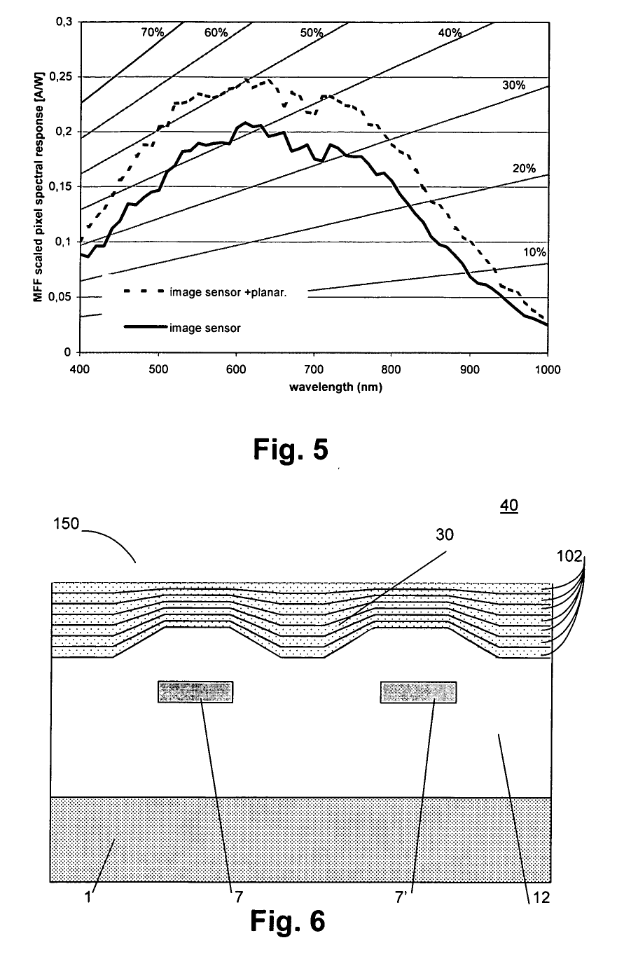

The improvement of the modified flat field pixel spectral response and quantum efficiency of a pixel is shown in FIG. 5: The spectral response and the quantum efficiency of a structure equivalent with the structure of the main embodiment with and without planarization polymer top layer is shown. The full line represents the spectral response of a monochrome image sensor device without a planarization layer, while the dotted line shows the spectral response of an image sensor device with a planarization layer. It can be seen that the increase in response of the device with additional planarization layer is about 20% compared to the device without additional planarization layer.

In an alternative embodiment of the present invention, an image sensor device 150 as in the previous embodiment is described, wherein the planarization layer consists of a set of sublayers having a refractive index that gradually changes from the refractive index of surrounding material 40, e.g. air, at the interface surrounding material 40/planarization layer 30, to the refractive index of the dielectric layer 12 near the planarization layer 30/dielectric layer 12 interface. A schematic overview of such an image sensor device is given in FIG. 6, showing the semiconductor substrate 1, part of the pixel structure, including the metal gates 7, 7′ and the covering dielectric layer 12, and the planarisation layer 30 comprising sublayers 102. The most optimum case would be a planarisation layer wherein the index of refraction changes continuously monotonously, from the refractive index of air to the refractive index of the dielectric layer.

The amount of reflection that occurs at an interface is determined by the difference in refractive index for both materials forming the interface. The larger the difference in refractive index, the larger the amount of reflection. If a stack of layers is used, the number of reflections is higher, but the total amount of reflected energy is smaller, even if the different layers do not fulfill the optimum conditions for anti reflective coatings, i.e. even if their thickness is not a multiple of λ/4.

In still another embodiment of the present invention, the materials and the thickness of the planarization layer 30 of the image sensor device 100 are chosen so that it has optimum anti-reflection properties. Although it is not possible that the planarization layer 30 is a real anti-reflective coating, as known from the prior art, as the planarization layer 30 has an inhomogeneous thickness to be able to level the surface and cancel the surface roughness, the refractive index of the planarization layer 30 and the thickness of certain regions in the planarization layer 30 can be selected so that it optimally fulfils the thickness and refractive index conditions for an anti-reflective coating. Returning to FIG. 2, the planarization layer 30 can be selected so that it has a refractive index n_{planarization}, between the refractive index of surrounding material, e.g. 1.0 in case of air, and the refractive index n_{dielectric} of the dielectric layer 12, and a maximum thickness d_{planarization} chosen to optimize the equation

$${n}_{planarisation} . {d}_{planarisation} = ( 2 l + 1 ) \cdot \frac{λ}{4} \qquad ( 4 )$$

The thickness of the planarization layer 30 is restricted at the downside as the planarization has to be thick enough to level the surface roughness of the underlying pixel structure. By selecting the maximum thickness of d_{planarization} based on equation 4, the planarization layer 30 acts as an anti-reflective coating for those regions where no influence of the thickness of the metal gates 7, 7′ occurs, i.e. example given the region situated between x-values xₐ and x_{b}. It is to be noted that these are the regions that do not suffer of reflection by the metal gates 7, 7′, and consequently the regions having the highest quantum efficiency for light coupled into the pixel structure. In other words, the additional amount of light coupled in into the device all can reach the semiconductor substrate, whereas in regions where the metal gates 7, 7′ are present, a fraction of the additional light gained due to the presence of an anti-reflective medium would be again lost due to reflection out of the device by the metal gates 7 and 7′. It is to be noted that the anti-reflective coating also has advantages if it does not have an optimised thickness. Without fulfilling the above equation, the reflection is already reduced partly. Furthermore, the material should be optimally selected to fulfill as good as possible the equations (5a) or (5b):
in general

$$\frac{{n}_{environment}}{{n}_{planarisation}} = \frac{{n}_{planarisation}}{{n}_{dielectric}} \qquad ( 5 a )$$
or in case of air
   nₚₗₐₙₐᵣᵢₛₐₜᵢₒₙ=\sqrt{n_{dielectric}} (5b)

The above embodiment has the advantage of combining both the reduction of the lensing effect and the anti-reflective properties for some regions of the device in one layer.

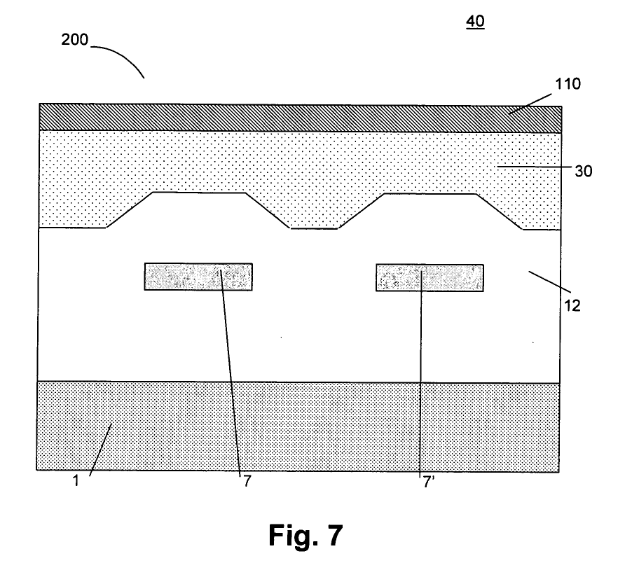

In another alternative embodiment, as illustrated in FIG. 7, the image sensor device 200 has both a separate planarisation layer 30 and an anti-reflective coating (ARC) 110 on top of the device layers. In this case, the anti-reflective coating 110 can be optimized, so that the coupling of the light into the layer can occur optimally in all regions of the image sensor device. In this case the thickness of the planarisation layer 30 can be solely determined by the surface roughness of the pixel structure from the image sensor device 200, while the thickness of the anti-reflective coating 110 is determined based on equation (1). The refractive index of the planarisation layer 30 and the refractive index of the anti-reflective coating 110 can then be determined so that the anti-reflective coating 110 functions well, while the planarisation layer 30 optimally solves the lensing problem and has a good light incoupling into the dielectric layer 12. Such a situation occurs e.g. when the refractive index of the ARC 110 is the square root of the refractive index of the planarisation layer 30 and the refractive index of the planarisation layer 30 lies closely to the refractive index of the dielectric layer 12. The anti-reflective coating 110 can be any type of anti-reflective coating available, and any technique to apply it may be used. This embodiment has the advantage that both the lensing effect and problems with reflections are handled and that the anti-reflective coating can be optimised providing anti-reflective properties for the whole surface of the image sensor device.

It is to be understood that although preferred embodiments, specific constructions and configurations, as well as materials, have been discussed herein for devices according to the present invention, various changes or modifications in form and detail may be made without departing from the scope and spirit of this invention.

1. A monochrome image sensor device (100) comprising a substrate (1) and a pixel structure wherein said monochrome image sensor device (100) further comprises a planarization layer (30) provided on top of the pixel structure, wherein the planarisation layer (30) at the same time is an anti reflective coating.

2. A monochrome image sensor device (100) according to claim 1, wherein the thickness of said planarization layer (30) and the refractive index of said planarisation layer (30) are optimized to also act as an anti-reflection medium for at least one region of said image sensor device (100).

3. A monochrome image sensor device (100) according to claim 1, wherein said planarization layer (30) consists of a polymer.

4. A monochrome image sensor device (100) according to claim 3, wherein said polymer is a photoresist.

5. A monochrome image sensor device (100) according to claim 1, wherein said pixel structure is a MOS-based pixel structure.

6. A monochrome image sensor device (100) according to claim 1, wherein said pixel structure is either an active pixel structure or a passive pixel structure.

7. A monochrome image sensor device (100) according to claim 2, wherein said planarization layer (30) comprises of a stack of films.

8. A monochrome image sensor device (100) according to claim 7, wherein the films in said stack have a refractive index that gradually changes from the refractive index of material (40) surrounding the sensor device (100) or a value as close as possible to said refractive index of material (40) surrounding the sensor device (100), to the refractive index of a top layer of said pixel structure.

9. A monochrome image sensor device (100) according to claim 7, wherein the films in said stack have a monotone continuously varying refractive index.

10. A monochrome image sensor device (100) according to claim 1, wherein said image sensor device (100) further comprises an additional anti-reflective coating on top of the planarization layer (30).

11. A method for making a monochrome image sensor device (100), comprising
providing a substrate (1),
applying a pixel structure on or in the substrate (1), and
providing a planarization layer (30) on top of the pixel structure.

12. A method according to claim 11, wherein applying a pixel structure comprises using MOS-based processing technology.

13. A method according to claim 11, wherein providing a planarization layer (30) on top is performed using spin coating or dip coating.

14. A method according to claim 11, wherein providing a planarization layer (30) comprises providing a stack of films.

15. A method according to claim 14, wherein providing a stack of films comprises providing a stack of films having gradually changing refractive indexes.

16. A method according to claim 11, furthermore comprising providing an anti-reflective coating on top of the planarization layer (30).

17. A method for improving light impingement on a monochrome image sensor device (100) comprising providing a planarisation layer (30) on top of a pixel structure of said image sensor device (100) to avoid a lensing effect, whereby the planarisation layer (30) is at the same time an anti-reflective coating.
